(19) United States
(12) Patent Application Publication
(10) Pub. No.: US 2024/0080037 A1
(43) Pub. Date: Mar. 7, 2024

(54) METHOD FOR DETERMINING AN IQ OFFSET

(71) Applicant: LAMBDA:4 ENTWICKLUNGEN GMBH, Hamburg (DE)

(72) Inventor: Rönne REIMANN, Hamburg (DE)

(73) Assignee: LAMBDA:4 ENTWICKLUNGEN GMBH, Hamburg (DE)

(21) Appl. No.: 18/262,504

(22) PCT Filed: Feb. 2, 2021
(86) PCT No.: PCT/EP2021/052445

§ 371 Date: Jul. 21, 2023

(51) Int. Cl. H03M 1/18; H03M 1/60

(52) U.S. Cl. CPC H03M 1/18; H03M 1/60

(57) ABSTRACT

The invention relates to the process of determining an IQ offset, in particular at low intermediate frequencies, in a receiver for electromagnetic radiation, in particular for digital data transmission. The aim of the invention is to provide a simple manner for determining the IQ offset, in particular quickly, reliably, and/or at low intermediate frequencies. According to the invention, this is achieved in particular in that the analog-digital converter is separated from the receiving devices and is electrically connected to at least one resistor by means of a switch in order to determine the IQ offset. While the analog-digital converter is connected to the resistor and not to the receiving devices, digital IQ values are obtained by means of the analog-digital converter. The digital IQ values obtained while the converter is connected to the resistor are used to determine the IQ offset.

The present invention relates to the determination of the IQ offset, in particular at low intermediate frequencies, in a receiver for electromagnetic radiation, in particular for digital data transmission.

Determination of an offset of the receiving device in the IG space for reception and decoding is known from prior art, particularly when using symbol alphabets with more than two symbols. This is usually achieved by considering a plurality of measurements. This is problematic, however, with a given signal level and the use of low intermediate frequencies, or when any other interference is present in the input signal in the receiver, as it is inaccurate and/or requires long measurement times and/or requires further assumptions. Various mathematical tricks are also known to reduce the problem. Such methods are known, for example, from DE10 2015 109 028 B9 or U.S. Pat. No. 10,862,728 B1.

The task of the invention is to provide a simple way of determining the IQ offset, in particular quickly, reliably and/or at a low intermediate frequency, in particular while reducing possible further interference.

The invention relates in particular to devices, applications and/or methods in which at least two antennas are used for reception, and in which a switch arrangement or at least one changeover switch is arranged between an A/D converter and the antennas. In particular, a device for heterodyne mixing to an intermediate frequency, at least one filter and/or at least one amplifier is arranged between the switch arrangement and/or the changeover switch.

The invention relates in particular to devices, applications and/or methods in which digital data transmission is used, in particular by means of the transmission of chips and/or symbols, in particular signals of a digital data transmission system, in particular a chip-synchronised and/or symbol-synchronised digital data transmission system.

Here a plurality of symbols and/or chips with a first symbol or chip rate are transmitted encoded in at least one first analogue data signal from the first object to the second object by means of the devices, the applications and/or the method.

The task is solved in particular by methods for determining an IQ offset of an analogue-digital converter arrangement in a receiver for receiving and decoding electromagnetically transmitted information, in particular for receiving and decoding symbol-encoded transmitted digital data, said analogue-digital converter arrangement having at least one switch and at least one analogue-digital converter and at least one, in particular at least also ohmic, resistor. Here digital IQ values of at least one electrical signal are obtained by means of the analogue-digital converter, whereby the at least one electrical signal is fed to the analogue-digital converter of at least one receiving device, in particular antenna, in particular successively from at least two receiving devices, in particular antennas, by means of the at least one switch. This enables the analogue-digital converter (also AD converter) to determine IQ values of the electrical signal, from which the digital information contained can be extracted. The invention is characterised in that, in order to determine the IQ offset by means of the at least one switch, the analogue-digital converter is disconnected from the receiving device(s) and connected electrically to the at least one resistor. While the analogue-digital converter is connected to the resistor and in particular not to the receiving device(s), digital IQ values are obtained by means of the analogue-digital converter. Thus, by means of the AD converter, in particular the signal received and processed via the resistor and the device electrically arranged between the resistor and the AD converter is sampled, in particular at least one I and one Q value, preferably at least ten each, are obtained here. The digital IQ values obtained while the converter is connected to the resistor are used to determine the IQ offset. In particular, the IQ offset is determined from the digital IQ values obtained during the connection to the resistor.

The task is also solved by using a resistor, in particular at least also an ohmic resistor, as a receiving means and/or as a means for generating an electrical signal for determining an IQ offset of an analogue-digital converter arrangement.

The task is also solved by a receiver, in particular a superheterodyne receiver, for receiving and decoding electromagnetically transmitted information, in particular for receiving and decoding symbol-encoded transmitted digital data, said analogue-digital converter arrangement having at least one switch and at least one analogue-digital converter and at least one, in particular at least also ohmic, resistor, said receiver being configured to obtain digital IQ values of at least one electrical signal by means of the analogue-digital converter, said receiver being configured to feed the at least one electrical signal to the analogue-digital converter from at least one receiving device, in particular successively from at least two receiving devices, by means of the at least one switch. The receiver is thereby characterised in that it is configured to disconnect the analogue-digital converter from the receiving devices and to electrically connect it to the at least one resistor in order to determine the IQ offset by means of the at least one switch, and to obtain digital data by means of the analogue-digital converter while the analogue-digital converter is connected to the resistor. The task is also solved by a data transmission system comprising at least one transmitter and at least one receiver, in particular two transceivers, in which at least one receiver according to the invention is included. The receiver according to the invention can be included as a receiver or as part of a transceiver.

The inventor has surprisingly discovered that by using the resistor instead of an antenna as receiver, a reliable IQ offset can be determined in a short time. This reduces the complexity of the determination, reduces the time required and makes it possible to repeatedly determine new IQ offsets to also increase accuracy over time.

It is a particular advantage if the receiver is part of a transmission system and/or operates according to a transmission standard and/or the application or method is carried out by means of a transmission system and/or standard. In particular, the transmission system is a Bluetooth system and/or the transmission standard is a Bluetooth standard. In particular, the transmission system is a digital data transmission system, in particular operating with QAM. In particular, the transmission system and/or transmission standard uses chips and/or symbols, in particular signals of a digital, in particular QAM, ASK, FSK, GFSK, PSK, QPSK, QAM, APSK and/or OFDM based, data transmission system and/or standard, in particular a chip-synchronised and/or symbol-synchronised digital data transmission system and/or standard. The transceivers are preferably configured to transmit a plurality of symbols and/or chips with a first symbol or chip rate encoded in at least one first analogue data signal (from) between the transceivers.

In a particularly advantageous embodiment, the method is used to determine the IQ offset for the reception of a clear carrier or a continuous wave, as at least optionally provided in recent Bluetooth standard versions and draft versions.

In particular, the electrical signal contains chips and/or symbols, in particular signals of a digital, in particular QAM, ASK, FSK, GFSK, PSK, QPSK, QAM, APSK and/or OFDM based, data transmission system, in particular a chip-synchronised and/or symbol-synchronised digital data transmission system. In particular, the method is a method for, in particular wireless, transmission of digital data, in particular encoded in an analogue signal. In particular, the system is a system for, in particular wireless, transmission of digital data, in particular encoded in an analogue signal.

In particular, the receiver and/or the system, in particular each transceiver, is configured to carry out a method and/or application according to the invention. In particular, the receiver, in particular each transceiver includes a calculation device for calculating the IQ offset from the IQ values obtained. In particular, the receiver, in particular each transceiver, comprises a control device which is configured to control the at least one switch, the calculation device and/or the AD converter to perform the method according to the invention.

In particular, the system, the transmission standard and/or the transmission system uses a symbol alphabet with more than two, in particular more than four, symbols and/or with symbols in which more than two, in particular more than four, bits can be encoded and/or are encoded and/or the receiver is configured to decode a symbol alphabet with more than two, in particular more than four, symbols and/or with symbols in which more than two, in particular more than four, bits can be encoded and/or are encoded.

The separation can also be effected by electrical switching elements which do not lead to a complete galvanic separation but only to a significant increase in the resistance, in particular by a factor of at least 100.

In particular, a switching device is arranged or used in such a way that, on the one hand, at least one receiving device, in particular at least two receiving devices, in particular antennas, in particular without amplifier and/or signal conditioning unit, and the resistor can each be selectively connected to, on the other hand, a signal conditioning unit which supplies the conditioned signal to the inputs of the A/D converter. The signal conditioning unit includes in particular at least one filter or filtering and/or at least one amplifier or amplification and/or one superheterodyne device and/or the superimposition. It is in particular part of the analogue-digital converter arrangement. By means of the superheterodyne device and/or the superimposition, the signal supplied via the switch is mixed in particular with a locally generated signal and converted in particular to a lower intermediate frequency. The superimposition device is configured for this purpose. For this purpose it contains in particular a local oscillator. The filter is in particular a bandpass filter. In particular, the signal is fed from the switch via the superheterodyne device and then the filter to the AD converter.

The offset is determined in particular so that it represents an I and a Q value by which the digital IQ values obtained during the connection of the analogue-digital converter to the resistor must be shifted so that they are centred around the zero point. The centring can thereby include a weighting of all the and/or the individual digital IQ values obtained, but preferably it is the unweighted mean of the digital IQ values obtained. Preferably, this should be zero after application of the offset, or the offset should be opposed to the mean value.

In a particularly advantageous embodiment, a new IQ offset is determined after a maximum of 10 ms. In this way, fluctuations can be detected and any resulting errors can be avoided.

In an advantageous embodiment, different IQ offsets are determined for different frequencies, in particular intermediate frequencies, different temperatures and/or different amplification factors; for this purpose, the method is carried out in particular once for each of the frequencies, temperatures and/or amplification factors using the respective frequency, temperature and/or amplification factor.

The IQ values are in particular in-phase values and quadrature values.

In particular, the at least one AD converter contains at least one AD converter for the in-phase value and at least one for the quadrature value.

In an advantageous embodiment, the IQ offset is determined by selecting the IQ offset such that digital IQ values obtained during the connection to the resistor and/or a subset of the obtained digital IQ values lie symmetrically around the zero point by applying the IQ offset. The receiver or transceiver is advantageously configured to do this.

In an advantageous embodiment, subsets of data are obtained from the digital I values obtained during the connection to the resistor, and a subset IQ offset is determined for a majority of the subsets of data in each case. In particular, an indicator for the quality of the IQ offset and/or at least one subset IQ offset is obtained by means of the subset IQ offsets. This can be determined by the differences and/or a metric of the subset IQ offsets, for example their variation and/or variance. The receiver or transceiver is advantageously configured to do this. This makes it possible to determine whether the determination should be improved by further IQ values and/or whether the determination should be repeated.

In a particularly advantageous embodiment, subsets of data are obtained from the digital IQ values obtained during the connection to the resistor, and a subset IQ offset is determined for each of a plurality of the subsets of data, said IQ offset being determined from the or from a subset of the subset IQ offsets. This can be done, for example, by averaging. The selection of the subset of the subset IQ offsets may be based, for example, on deviations of a mean value or other metrics, such as the variation within the corresponding data subset. The receiver or transceiver is advantageously configured to do this.

In this way, the determination can be improved, for example by not taking into account IQ values for which there is a particularly strong interference.

In a particularly advantageous embodiment, the receiver, in particular the analogue-digital converter arrangement, includes a device for mixing to an intermediate frequency and/or the receiver uses an intermediate frequency, whereby said intermediate frequency is selected such that the time used to measure the digital IQ values obtained during the connection to the resistor for determination of the IQ offset is shorter than the reciprocal of the intermediate frequency multiplied by five, in particular by three, and/or the intermediate frequency is lower than 100 kHz, in particular lower than 10 kHz. The receiver or transceiver is advantageously configured to do this. Particularly with such combinations of intermediate frequency and measurement time, the advantages of the invention become particularly apparent, since the disadvantages of the prior art result in particularly strong interference in these constellations.

In particular, the method is carried out for determining an IQ offset for the reception of signals for determining the angle of departure (AoD) or angle of arrival (AoA) and/or for phase-based distance measurement. Here, the advantages of the invention come particularly to bear, since a low intermediate frequency of less than 100 kHz, in particular less than 10 kHz, is particularly advantageous for this purpose in order to minimise errors in the determination/measurement caused by time inaccuracies. In this respect, the benefit of the invention is particularly large since the measurement time and/or measurement error can be significantly reduced. In particular, the method is thus part of a method for determining the angle of departure (AoD), angle of arrival (AoA) and/or for phase-based distance measurement. In particular, the application is thus an application for determining the angle of departure (AoD), angle of arrival (AoA) and/or for phase-based distance measurement. In particular, the receiver and/or the system is configured for determining the angle of departure (AoD), angle of arrival (AoA) and/or for phase-based distance measurement.

In particular, the intermediate frequency is a low intermediate frequency, which is especially the case if no or only less than three complete waves are included over the measurement period for determining the IQ offset. This is because the fewer complete waves are included, the greater the error of the IQ offset due to the incomplete waves included in the IQ values. This can be reduced, as the inventor has recognised, by connecting the A/D converter to a resistor to determine the IQ offset.

In an advantageous embodiment, the analogue-digital converter arrangement comprises at least one device for heterodyne mixing of the signal supplied by means of the switch before it reaches the analogue-digital converter, and the electrical signal supplied by means of the switch is converted to an intermediate frequency by means of the device for heterodyne mixing. The receiver or transceiver is advantageously configured to do this. This allows the subsequent circuitry to be simplified and the work for digitisation and decoding to be reduced.

A heterodyne receiver is in particular characterised in that it comprises, as a device for heterodyne mixing, means for converting the variable or constant input frequency to an, in particular lower and in particular constant, intermediate frequency, in particular between switch and AD converter.

The method and/or the application includes in particular the conversion of the variable or constant input frequency to an, in particular lower and in particular constant, intermediate frequency, in particular between switch and AD converter.

The at least one switch is advantageously used to electrically connect and disconnect the analogue-digital converter of the analogue-digital converter arrangement and/or the analogue-digital transceiver arrangement to and from the resistor and/or to connect and disconnect it to and from at least one receiver device. The receiver or transceiver is advantageously configured to do this.

The receiving device(s) advantageously comprise(s) one or more antenna(s). In particular, the antenna signal is fed to the switch without amplification. The receiver or transceiver is advantageously configured to do this. This allows the reliability of the method to be increased. Particularly preferably, no amplifier, in particular no LNA, is arranged and/or used between AD converter and antenna, in particular not between switch and antenna and/or receiving device.

Preferably, the receiver is configured, in particular exclusively, to use the digital IQ values obtained during the connection to the resistor to determine the IQ offset.

In a particularly advantageous embodiment, the resistor is an ohmic resistor and/or the resistor has a resistance in the range of 30 to 150 ohms, in particular adapted to the RF circuit of the receiver used, in particular of 50 ohms.

1. A method for determining an offset of an analogue-digital converter arrangement in a receiver for receiving and decoding electromagnetically transmitted information, said analogue-digital converter arrangement having a switch and an analogue-digital converter and a resistor wherein digital values of at least one electrical signal are obtained by means of the analogue-digital converter, with the at least one electrical signal being fed to the analogue-digital converter from at least one receiving device by means of the switch, wherein in order to determine the offset by means of the switch, the analogue-digital converter is disconnected from the at least one receiving device and is electrically connected to the at least one resistor and, while the analogue-digital converter is connected to the resistor, digital values are obtained by means of the analogue-digital converter, and that the digital values obtained during the connection to the resistor are used to determine the IQ offset; and wherein the digital values are IQ values and the offset is an IQ offset and that no amplifier is arranged between the switch and the at least one receiving device or that at least one amplifier is arranged between the switch and the analogue-digital converter.

2. The method according to claim 1, wherein the offset is determined by selecting the IQ offset such that digital IQ values obtained during the connection to the resistor or a subset of the obtained digital IQ values lie symmetrically around the zero point by applying the IQ offset.

3. The method according to claim 1, wherein subsets of data are obtained from the digital data obtained during the connection to the resistor, and a subset IQ offset is determined for a plurality of the subsets of data in each case, and wherein an indicator for the quality of the IQ offset or at least one subset IQ offset is obtained by means of the subset IQ offsets.

4. The method according to claim 1, wherein subsets of data are obtained from the digital IQ values obtained during the connection to the resistor, and a subset IQ offset is determined for each of a plurality of the subsets of data, said IQ offset being determined from the or from a subset of the subset IQ offsets.

5. The method according to claim 1, wherein the receiver or the analogue-digital converter arrangement includes a device for mixing to an intermediate frequency or the receiver uses an intermediate frequency, said intermediate frequency being selected such that a time used to measure the digital IQ values obtained during the connection to the resistor for determination of the IQ offset is shorter than a reciprocal of the intermediate frequency multiplied by five or the intermediate frequency is lower than 100 kHz.

6. The method according to claim 1, wherein the analogue-digital converter arrangement comprises at least one device for heterodyne mixing of the signal supplied by means of the switch before the signal reaches the analogue-digital converter, and the electrical signal supplied by means of the switch is converted to an intermediate frequency by means of the device for heterodyne mixing.

7. The method for determining an angle of departure (AoD), an angle of arrival (AoA) or for phase-based distance measurement, wherein at least one radio signal is transmitted from a transmitter to the receiver and at least one phase measurement is carried out on the at least one received radio signal at the receiver, wherein based on the at least one phase measurement, the angle of departure of the at least one radio signal at the transmitter (AoD), the angle of arrival of the radio signal at the receiver (AoA) or a distance between the transmitter and the receiver is determined, with the IQ offset of the receiver being used for the at least one phase measurement determined according to claim 1.

8. A use of an resistor as a receiving means or for generating an electrical signal to determine an offset of an analogue-digital converter arrangement wherein at least one switch is used to electrically connect and disconnect the analogue-digital converter of the analogue-digital converter arrangement or an analogue-digital transceiver arrangement to and from the resistor or to connect and disconnect the analogue-digital converter to and from at least one receiving device; and wherein the offset is an IQ offset and that no amplifier is arranged between the switch and the receiving means or that at least one amplifier is arranged between the switch and the analogue-digital converter.

9. (canceled)

10. The use according to claim 8, wherein the use includes a use of the IQ offset for measuring at least one, phase position of at least one radio signal emitted by a transmitter and received by at least one antenna by means of the analogue-digital converter arrangement, wherein the at least one phase position measurement is carried out using or correcting by means of the determined IQ offset and wherein the at least one phase position measurement is used to determine an angle of departure (AoD) or an angle of arrival (AoA) of the at least one radio signal or for phase-based distance measurement between the transmitter and the at least one antenna.

11. A receiver for receiving and decoding electromagnetically transmitted information, wherein an analogue-digital converter arrangement has at least one switch and at least one analogue-digital converter and at least one resistor, said receiver being configured to obtain digital IQ values from at least one electrical signal by means of the analogue-digital converter, said receiver being configured to feed the at least one electrical signal to the analogue-digital converter from at least one receiving device, by means of the at least one switch, wherein the receiver is configured to disconnect the analogue-digital converter from the at least one receiving device and to connect the analogue-digital converter electrically to the at least one resistor in order to determine an offset by means of the at least one switch, and to obtain digital data by means of the analogue-digital converter while the analogue-digital converter is connected to the resistor, wherein the offset is an IQ offset and wherein no amplifier is arranged between the at least one switch and an antenna or the at least one receiving device, or wherein at least one amplifier is arranged between the at least one switch and the analogue-digital converter.

12. The receiver according to claim 11, wherein said receiver is configured to use the digital data obtained during the connection to the resistor to determine the IQ offset.

13. A data transmission system comprising at least one transmitter and at least one receiver according to claim 11.
